(19) United States
(12) Patent Application Publication
(10) Pub. No.: US 2013/0071792 A1
(43) Pub. Date: Mar. 21, 2013

(54) METHOD FOR FABRICATING LIQUID CRYSTAL DISPLAY DEVICE

(71) Applicants: Yasuyoshi Kaise, Osaka-shi (JP); Mutsumi Nakajima, Osaka-shi (JP); Keisuke Yoshida, Osaka-shi (JP); Yasutoshi Tasaka, Osaka-shi (JP); Keiichi Ina, Osaka (JP)

(72) Inventors: Yasuyoshi Kaise, Osaka-shi (JP); Mutsumi Nakajima, Osaka-shi (JP); Keisuke Yoshida, Osaka-shi (JP); Yasutoshi Tasaka, Osaka-shi (JP); Keiichi Ina, Osaka (JP)

(73) Assignee: SHARP KABUSHIKI KAISHA, Osaka-shi, Osaka (JP)

(21) Appl. No.: 13/699,683

(22) PCT Filed: Apr. 5, 2011
(86) PCT No.: PCT/JP2011/002028

§ 371 Date: Nov. 23, 2012

(30) Foreign Application Priority Data
May 26, 2010 (JP) 2010-120673

(51) Int. Cl. G03F 7/20

(52) U.S. Cl. 430/320

(57) ABSTRACT

An amount of exposure of the photosensitive resin is controlled using a photomask in an exposure treatment. The photosensitive resin subjected to the exposure treatment is developed, thereby simultaneously forming a protrusion which regulates the alignment of liquid crystal molecules comprising the liquid crystal layer, and a photo spacer.

### TECHNICAL FIELD

The present disclosure relates to methods for fabricating liquid crystal display devices in which a pair of substrates are layered, with a predetermined space interposed therebetween, and liquid crystal is sealed in the gap between the pair of substrates.

### BACKGROUND ART

Liquid crystal display devices, which are a type of display device, are thin and light, and thus widely used as mobile devises, such as laptop computers and mobile phones, and AV devices, such as liquid crystal television.

In general, liquid crystal display devices include a pair of substrates arranged to face each other (i.e., a thin film transistor (TFT) substrate and a color filter (CF) substrate), and a liquid crystal layer interposed between the pair of substrates. The liquid crystal display devices further include a frame-like sealing material for having the pair of substrates adhere to each other and sealing liquid crystal between the substrates, and a plurality of spacers for regulating a thickness (i.e., a cell gap) of the liquid crystal layer.

Examples of the liquid crystal display device include an active matrix type liquid crystal display device in which an active element such as a TFT is provided to correspond to each of pixel regions, and a wiring provided on an insulating substrate such as a glass substrate is connected, via the active element, to a pixel electrode provided to correspond to each of the pixel regions.

In this active matrix type liquid crystal display device, the active element is provided between the wiring and the pixel electrode so as to be connected to the wiring and the pixel electrode, and the active element controls a potential applied to the pixel electrode from the wiring.

With an increase in amount of information, the liquid crystal display devices are requested to display more information, and there is an increasing demand from the market for higher contrast and wider viewing angle.

Thus, in recent years, a vertically-aligned mode using a vertically-aligned liquid crystal layer is receiving attention as a display mode of a transflective type liquid crystal display device capable of higher contrast and wider viewing angle. In general, the vertically-aligned liquid crystal layer is made of an alignment film containing vertically-aligned liquid crystal molecules, and a liquid crystal material with negative dielectric anisotropy.

Here, liquid crystal display devices having a protrusion which protrudes toward the liquid crystal layer to achieve a stable alignment state of the liquid crystal have been suggested. More specifically, for example, a liquid crystal display device having, on at least one of electrodes provided on opposing surfaces of the pair of substrates, a protrusion for regulating the alignment of the liquid crystal is disclosed (see, e.g., Patent Document 1).

### CITATION LIST

### Patent Document

Patent Document 1: Japanese Patent Application No. 2005-165191

### SUMMARY OF THE INVENTION

### Technical Problem

However, in the above conventional liquid crystal display device, it is necessary to perform another step for forming the protrusion for regulating the alignment of the liquid crystal. Thus, the number of steps and the costs are increased.

The present disclosure was made in view of the above problems, and it is an objective of the invention to provide a method for fabricating a liquid crystal display device in which a protrusion can be formed without increasing the number of fabrication steps.

### Solution to the Problem

To achieve the above objective, a method for fabricating a liquid crystal display device of the present disclosure includes a first substrate; a second substrate located to face the first substrate; a liquid crystal layer provided between the first substrate and the second substrate; a plurality of photo spacers provided between the first substrate and the second substrate to regulate a thickness of the liquid crystal layer; and a protrusion provided between the first substrate and the second substrate to regulate alignment of liquid crystal molecules included in the liquid crystal layer, and in which a display region that displays an image is comprised of a plurality of pixels, the method at least including: preparing an insulating substrate as the first substrate or the second substrate, providing a photosensitive resin onto the insulating substrate, performing an exposure treatment by controlling an amount of exposure of the photosensitive resin using a photomask, and developing the photosensitive resin subjected to the exposure treatment, thereby forming the protrusion and the photo spacers at the same time.

In this structure, the protrusion and the photo spacers can be formed at the same time using the same material (i.e., a photosensitive resin). Accordingly, it is not necessary to provide another step for forming the protrusion which regulates the alignment of the liquid crystal molecules comprising the liquid crystal layer. As a result, the protrusion can be obtained without increasing the number of fabrication steps, which can prevent an increase in costs.

According to the method for fabricating the liquid crystal display device of the present disclosure, the photomask is preferably a gray-tone mask or a half-tone mask.

In this structure, the exposure treatment with different amounts of exposure can be easily performed on the photosensitive resin. As a result, the amount of exposure of the photosensitive resin can be easily controlled.

According to the method for fabricating the liquid crystal display device of the present disclosure, it is preferable that each of the pixels includes a transmissive region which transmits light to display an image and a reflection region which reflects light to display an image, and the protrusion is provided in at least one of the transmissive region or the reflection region.

In this structure, it is possible to regulate the alignment of the liquid crystal molecules comprising the liquid crystal layer in at least one of the transmissive region or the reflection region.

According to the method for fabricating the liquid crystal display device of the present disclosure, the protrusion is provided preferably at a center portion of the transmissive region.

In this structure, the liquid crystal molecules can be radially arranged in a well-balanced manner across the transmissive region, with the center portion of the transmissive region serving as a center of the alignment.

According to the method for fabricating the liquid crystal display device of the present disclosure, the protrusion is provided preferably at a center portion of the reflection region.

In this structure, the liquid crystal molecules can be radially arranged in a in a well-balanced manner across the reflection region, with the center portion of the reflection region serving as a center of the alignment.

According to the method for fabricating the liquid crystal display device of the present disclosure, a thickness of the protrusion and a thickness of at least one of the photo spacers are preferably the same.

In this structure, it is possible to increase the number of structures for regulating the thickness of the liquid crystal layer without decreasing a transmittance or a reflectance. Thus, it is possible to effectively reduce distortion of an image, etc., which occurs when the display surface is pressed.

According to the method for fabricating the liquid crystal display device of the present disclosure, the photosensitive resin may be an acrylic photosensitive resin.

### Advantages of the Invention

According to the present disclosure, it is possible to form the protrusion without increasing the number of fabrication steps, and thus possible to reduce an increase in costs.

### BRIEF DESCRIPTION OF THE DRAWINGS

FIG. 1 is a plan view of a general structure of a liquid crystal display device according to an embodiment of the present disclosure.

FIG. 2 is a cross-sectional view of the general structure of the liquid crystal display device according to the embodiment of the present disclosure.

FIG. 3 is a configuration of an equivalent circuit of the liquid crystal display device according to the embodiment of the present disclosure.

FIG. 4 is a cross-sectional view of a general structure of a TFT substrate which comprises the liquid crystal display device according to the embodiment of the present disclosure.

FIG. 5 is a cross-sectional view of a general structure of a display portion of a pixel of a liquid crystal display panel which comprises the liquid crystal display device according to the embodiment of the present disclosure.

FIG. 6 is a plan view of a structure of the display portion of the pixel of the liquid crystal display panel which comprises the liquid crystal display device according to the embodiment of the present disclosure.

FIG. 7 is a cross-sectional view for explaining a method for fabricating a CF substrate which comprises the liquid crystal display device according to the embodiment of the present disclosure.

FIG. 8 is a cross-sectional view for explaining the method for fabricating the CF substrate which comprises the liquid crystal display device according to the embodiment of the present disclosure.

FIG. 9 is a cross-sectional view for explaining the method for fabricating the CF substrate which comprises the liquid crystal display device according to the embodiment of the present disclosure.

FIG. 10 is a cross-sectional view for explaining the method for fabricating the CF substrate which comprises the liquid crystal display device according to the embodiment of the present disclosure.

FIG. 11 is a cross-sectional view for explaining the method for fabricating the CF substrate which comprises the liquid crystal display device according to the embodiment of the present disclosure.

FIG. 12 is a cross-sectional view for explaining the method for fabricating the CF substrate which comprises the liquid crystal display device according to the embodiment of the present disclosure.

FIG. 13 is a plan view illustrating a photomask used in an exposure treatment in the method for fabricating the liquid crystal display device according to the embodiment of the present disclosure.

FIG. 14 is a cross-sectional view showing a variation of the display portion of the pixel of the liquid crystal display panel according to the present disclosure.

FIG. 15 is a cross-sectional view showing another variation of the display portion of the pixel of the liquid crystal display panel according to the present disclosure.

### DESCRIPTION OF EMBODIMENTS

A structure of a liquid crystal display device according to an embodiment of the present disclosure, and a method for fabricating the liquid crystal display device will be described in detail below based on the drawings. The present disclosure is not limited to the embodiment described below.

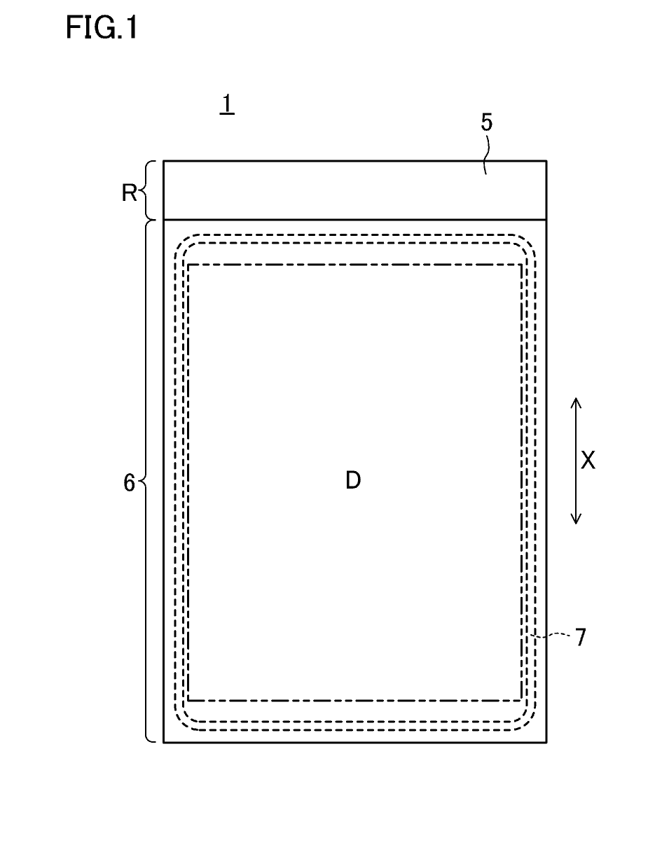

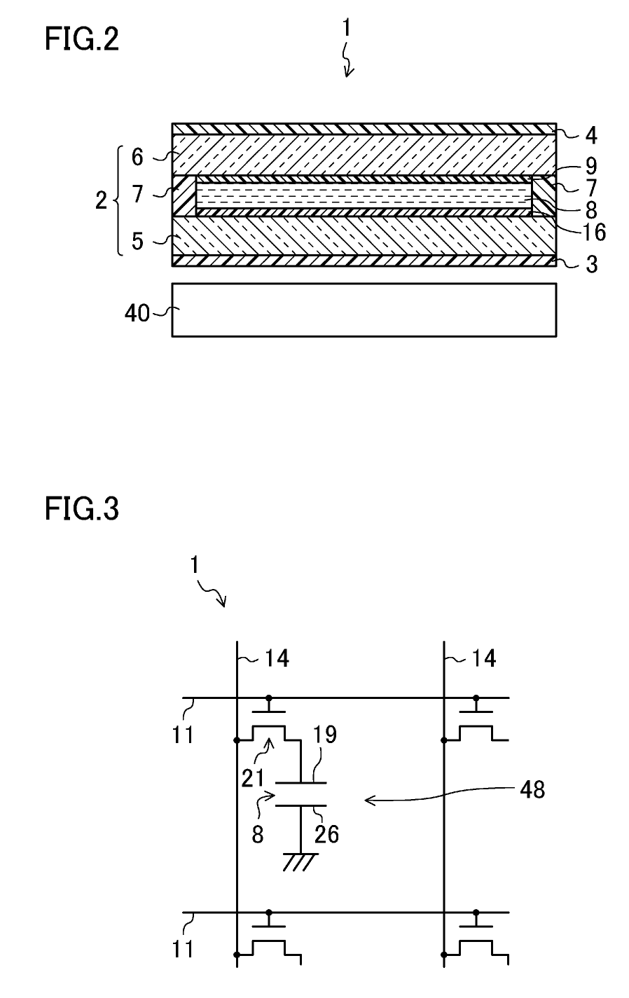

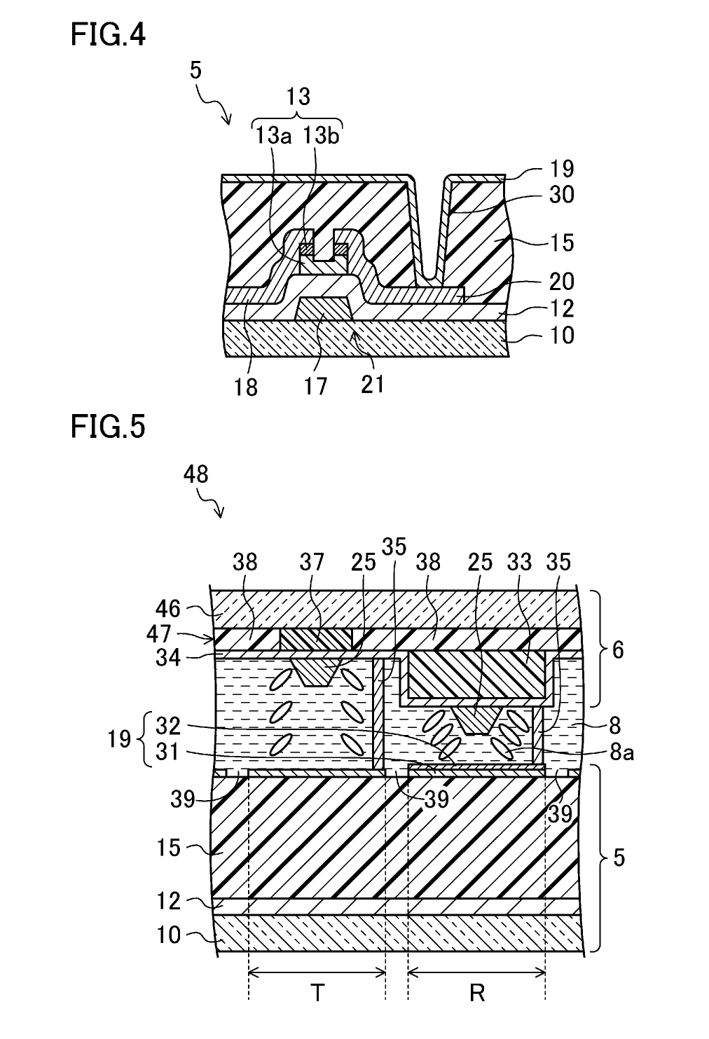

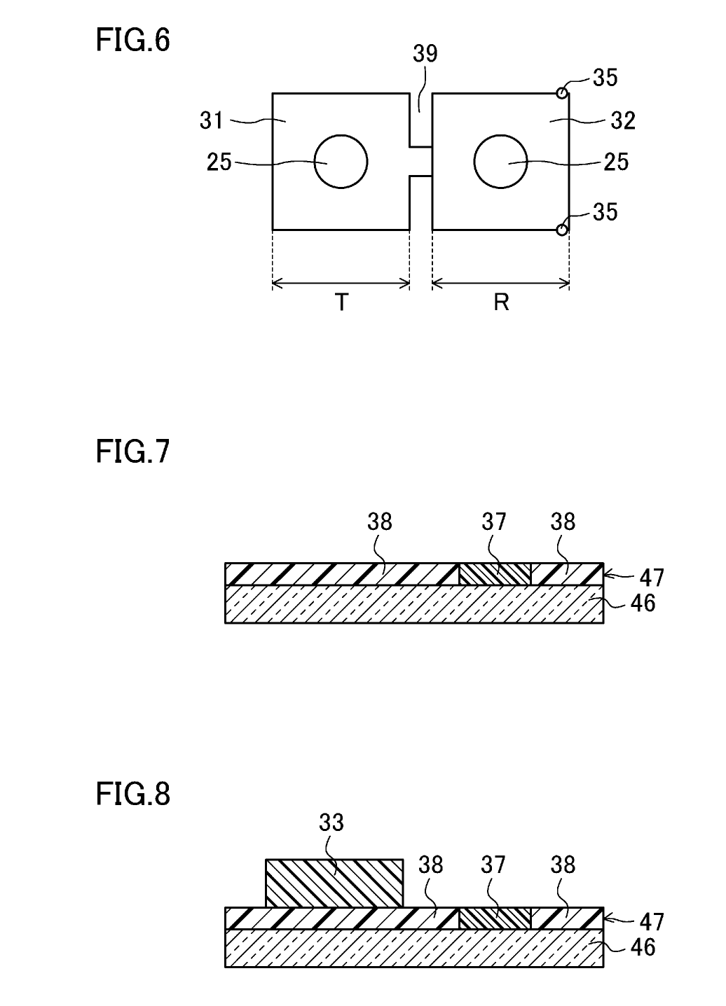

FIG. 1 is a plan view of a general structure of a liquid crystal display device according to an embodiment of the present disclosure. FIG. 2 is a cross-sectional view of the general structure of the liquid crystal display device according to the embodiment of the present disclosure. FIG. 3 is a configuration of an equivalent circuit of the liquid crystal display device according to the embodiment of the present disclosure. FIG. 4 is a cross-sectional view of a general structure of a TFT substrate which comprises the liquid crystal display device according to the embodiment of the present disclosure. FIG. 5 is a cross-sectional view of a general structure of a display portion of a pixel of a liquid crystal display panel which comprises the liquid crystal display device according to the embodiment of the present disclosure. FIG. 6 is a plan view of a structure of the display portion of the pixel of the liquid crystal display panel which comprises the liquid crystal display device according to the embodiment of the present disclosure. For convenience of description, a polarizing plate is not shown in FIG. 1. For convenience of description, an alignment film is not shown in FIG. 4 and FIG. 5.

As shown in FIG. 1 and FIG. 2, a liquid crystal display device 1 includes a liquid crystal display panel 2 and a backlight unit 40. The liquid crystal display panel 2 includes a TFT substrate (a thin film transistor substrate) 5 which is a first substrate with a polarizing plate 3 provided on its outer surface, and CF substrate (a color filter substrate) 6 which is a second substrate located to face the TFT substrate 5 with a polarizing plate 4 provided on its outer surface. The liquid crystal display device 1 also includes a liquid crystal layer 8 which is a display medium layer sandwiched between the TFT substrate 5 and the CF substrate 6, and a sealing material 7 sandwiched between the TFT substrate 5 and the CF substrate 6 to have the TFT substrate 5 and the CF substrate 6 adhere to each other, and having a frame-like shape to seal the liquid crystal layer 8.

The sealing material 7 is formed to surround the liquid crystal layer 8. The TFT substrate 5 and the CF substrate 6 are bonded together with this sealing material 7. Further, as shown in FIG. 5, the liquid crystal display device 1 includes a plurality of photo spacers 35 for regulating a thickness (i.e., a cell gap) of the liquid crystal layer 8.

As shown in FIG. 1, the liquid crystal display device 1 is in a rectangular shape. The upper edge of the TFT substrate 5 protrudes from the CF substrate 6 in a longitudinal direction X of the liquid crystal display device 1, and a plurality of display wirings, such as gate lines and source lines described later, are extended to the protruded region and form a terminal region R.

Further, in the liquid crystal display device 1, a display region D which displays an image is defined by a region where the TFT substrate 5 and the CF substrate 6 overlap one another. The display region D is comprised of a plurality of pixels 48, i.e., smallest units of an image (see FIG. 3 and FIG. 5) arranged in a matrix.

The sealing material 7 is in a rectangular frame-like shape which surrounds the entire circumference of the display region D, as shown in FIG. 1.

The TFT substrate 5 includes a plurality of switching elements arranged in a matrix. More specifically, as shown in FIG. 3 and FIG. 4, the TFT substrate 5 includes an insulating substrate 10 such as a glass substrate, a plurality of gate lines 11 provided on the insulating substrate 10 and extending in parallel to each other, a gate insulating film 12 formed to cover the gate lines 11, and a plurality of source lines 14 provided on the gate insulating film 12 and extending in parallel to each other in a direction orthogonal to the gate lines 11. The TFT substrate 5 also includes thin film transistors (TFTs) 21, that is, a plurality of switching elements each of which is provided at a portion where the gate line 11 and the source line 14 intersect one another, an interlayer insulating film 15 which covers the source lines 14 and the TFTs 21, a plurality of pixel electrodes 19 provided on the interlayer insulating film 15 in a matrix, and connected to the respective TFTs 21, and an alignment film 16 (see FIG. 2) which covers the pixel electrodes 19.

The rectangular region defined by the gate lines 11 and the source lines 14 is a region of each pixel 48. Each of the pixel electrodes 19 is made of a transparent conductive material, such as indium tin oxide (ITO) or indium zinc oxide (IZO).

As shown in FIG. 4, each of the TFTs 21 includes a gate electrode 17 from which a corresponding one of the gate lines 11 protrudes laterally, a gate insulating film 12 which covers the gate electrode 17, an island-shaped semiconductor layer 13 provided on the gate insulating film 12 and above the gate electrode 17, and a source electrode 18 and a drain electrode 20 which face each other on the semiconductor layer 13.

The source electrode 18 is a portion of a corresponding one of the source lines 14 which protrudes laterally. The drain electrode 20 is connected to a corresponding one of the pixel electrodes 19 via a contact hole 30 formed in the interlayer insulating film 15, as shown in FIG. 4.

The semiconductor layer 13 includes, as shown in FIG. 4, an intrinsic amorphous silicon layer 13a as a lower layer, and an n⁺ amorphous silicon layer 13b doped with phosphorus as an upper layer. A portion of the intrinsic amorphous silicon layer 13a which is not covered by the source electrode 18 and the drain electrode 20 forms a channel region.

Each of the pixel electrodes 19 is formed on a flat surface of the interlayer insulating film 15, using a material such as ITO, and forms a transparent electrode. As shown in FIG. 5, each of the pixel electrodes 19 includes a cutout 39 at a predetermined position, and the pixels 48 are divided into pixel patterns by this cutout 39.

In a display portion of each of the pixels 48 of the liquid crystal display panel 2, a reflection region R is defined by a reflection electrode 32 as shown in FIG. 5, and a transmissive region T is defined by a transparent electrode 31 not covered by the reflection electrode 32.

The reflection region R is a region which reflects light entering from a display surface side (that is, light entering from the CF substrate 6) to display an image. The transmissive region T is a region which transmits light of the backlight unit 40 entering from a back surface side (that is, light entering from the TFT substrate 5) to display an image.

Examples of the materials for the interlayer insulating film 15 may include, but not specifically limited to, silicon oxide (SiO₂), silicon nitride (SiNx (x is a positive number)), etc. A thickness of the interlayer insulating film 15 is preferably 600 nm or more and 1000 nm or less. This is because if the thickness of the interlayer insulating film 15 is less than 600 nm, it may be difficult to planarize the interlayer insulating film 15, and if the thickness is more than 1000 nm, it may be difficult to form the contact hole 30 by etching.

As shown in FIG. 5, the CF substrate 6 includes an insulating substrate 46, such as a glass substrate, a color filter layer 47 formed on the insulating substrate 46, and a transparent dielectric layer 33 which compensates an optical path difference between the reflection region R and the transmissive region T in the reflection region R of the color filter layer 47. The CF substrate 6 also includes a common electrode 34 which covers the transmissive region T of the color filter layer 47 and the transparent dielectric layer 33 (i.e., the reflection region R), the columnar photo spacers 35 provided on the common electrode 34, and an alignment film 9 (see FIG. 2) which covers the common electrode 34 and the photo spacers 35.

The color filter layer 47 includes a color layer 38 (a red color layer R, a green color layer G, and a blue color layer B) provided for each pixel, and a black matrix 37 as a light shielding film. The black matrix 37 is located between adjacent color layers 38 to partition the plurality of color layers 38 from one another. Examples of the pixel patterns may include complementary colors of cyan, magenta, and yellow, other than the combination of RGB.

As shown in FIG. 5, the CF substrate 6 includes a protrusion 25 provided on the common electrode 34 to regulate the alignment of liquid crystal molecules 8a which comprise the liquid crystal layer.

As shown in FIG. 5 and FIG. 6, the protrusion 25 includes a plurality of protrusions 25. In the reflection region R, the protrusion 25 is provided on the common electrode 34 at a center portion of the reflection electrode 32, that is, a center portion of the reflection region R. Further, as shown in FIG. 5 and FIG. 6, in the transmissive region T, the protrusion 25 is provided on the common electrode 34 at a center portion of the transparent electrode 31, that is, a center portion of the transmissive region T.

The photo spacers 35 are made of a photosensitive resin (e.g., an acrylic photosensitive resin) and formed by photolithography.

According to the present embodiment, similar to the photo spacers 35, the protrusions 25 are made of a photosensitive resin (e.g., an acrylic photosensitive resin) and formed by photolithography.

Further, the protrusion 25 has a truncated cone shape which protrudes toward the TFT substrate 5 facing the protrusion 25, and there is a gap between the top of the protrusion 25 and the TFT substrate 5. The shape of the protrusion 25 is not limited, and may be in a cone shape, a pyramid shape, or a truncated pyramid shape, etc.

The black matrix 37 is made of a metal material such as tantalum (Ta), chromium (Cr), molybdenum (Mo), nickel (Ni), titanium (Ti), copper (Cu), aluminum (Al), a resin material in which a black pigment such as carbon is dispersed, or a resin material in which optically transparent color layers of a plurality of colors are layered, etc.

The liquid crystal layer 8 is located between the TFT substrate 5 and the CF substrate 6. The liquid crystal layer 8 contains a nematic liquid crystal material with negative dielectric anisotropy, and further contains a chiral material depending on need. When no voltage is applied to the liquid crystal layer 8, the liquid crystal molecules 8a (i.e., a liquid crystal material of the liquid crystal layer 8) are aligned approximately perpendicular to the TFT substrate 5 and the CF substrate 6 due to the effect of alignment regulation of the alignment films 9, 16.

When a voltage is applied to the liquid crystal layer 8, an oblique electric field is generated in a region around the pixel electrode 19 and near the cutout 39. Due to the alignment regulation of this oblique electric field, a liquid crystal domain which provides radially-tilted alignment is formed in each of the plurality of pixel patterns, and a direction to which the liquid crystal molecules 8a are tilted due to the electric field is determined. As shown in FIG. 5, the radially-tilted alignment of the liquid crystal molecules 8a is further stabilized due to the effect of alignment regulation of the protrusion 25, which protrudes toward the liquid crystal layer 8 from a surface of the CF substrate 6 facing the liquid crystal layer 8.

The transflective type liquid crystal display device 1 having the above structure is configured such that light entering from the CF substrate 6 is reflected on the reflection electrode 32 in the reflection region R, and light of the backlight unit 40 entering from the TFT substrate 5 is transmitted through the transmissive region T.

In the liquid crystal display device 1, each of the pixel electrodes 19 forms one pixel. When a gate signal is sent to each of the pixels from the gate line 11 to turn on the TFT 21, a source signal is sent from the source line 14 to generate a predetermined electric charge in the pixel electrode 19 through the source electrode 18 and the drain electrode 20. As a result, a potential difference occurs between the pixel electrode 19 and the common electrode 34, and a predetermined voltage is applied to the liquid crystal layer 8. The liquid crystal display device 1 is configured to display an image by adjusting a transmittance of light from the backlight unit 40, based on the phenomenon that the alignment state of the liquid crystal molecules 8a changes according to the magnitude of the applied voltage.

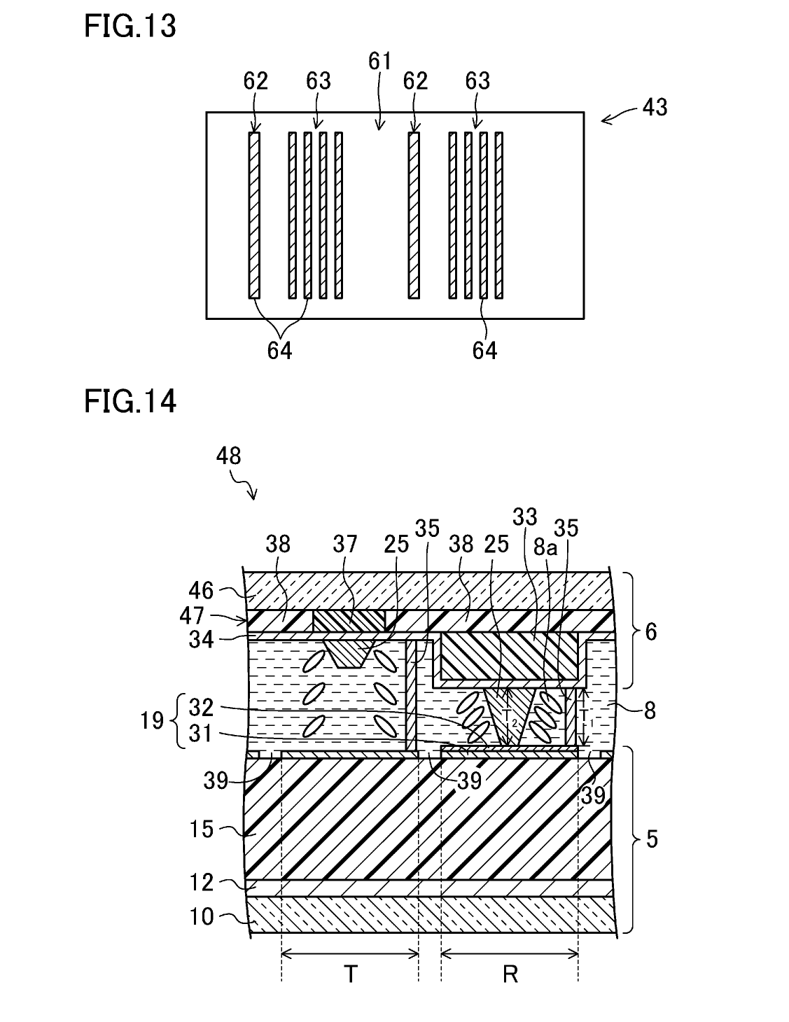

Now, an example method for fabricating the liquid crystal display device of the present embodiment will be described. FIG. 7 to FIG. 12 are cross-sectional views for explaining a method for fabricating the CF substrate which comprises the liquid crystal display device according to the embodiment of the present disclosure. FIG. 13 is a plan view illustrating a photomask used in an exposure treatment. The fabrication method described below is merely an example, and the method for fabricating the liquid crystal display device 1 of the present disclosure is not limited to the method described below. The fabrication method according to the present embodiment includes a TFT substrate formation step, a CF substrate formation step, and a substrate bonding step.

<TFT Substrate Formation Step>

First, a metal film is formed on the entire insulating substrate 10 by sputtering (for example, a titanium film, an aluminum film, and a titanium film are sequentially formed), and thereafter, patterning is performed by photolithography to obtain the gate lines 11 and the gate electrode 17 with a thickness of about 4000 Å.

Next, a silicon nitride film, for example, is formed on the entire substrate on which the gate lines 11 and the gate electrode 17 are formed, by plasma chemical vapor deposition (CVD) to obtain the gate insulating film 12 with a thickness of about 4000 Å.

Next, an intrinsic amorphous silicon film (having a thickness of about 2000 Å) and an n⁺ amorphous silicon film (having a thickness of about 500 Å) doped with phosphorus, for example, are sequentially formed by plasma CVD on the entire substrate on which gate insulating film 12 is formed, and thereafter, patterning is performed to obtain on the gate electrode 17 an island-shaped semiconductor formation layer in which the intrinsic amorphous silicon layer and the n⁺ amorphous silicon layer are layered.

Next, an aluminum film and a titanium film, for example, are sequentially formed on the entire substrate on which the semiconductor formation layer is formed, by sputtering, and thereafter, patterning is performed by photolithography to obtain the source lines 14, the source electrode 18, and the drain electrode 20 with a thickness of about 2000 Å.

Next, the n⁺ amorphous silicon layer of the semiconductor formation layer is etched using the source electrode 18 and the drain electrode 20 as a mask, thereby patterning the channel region and obtaining the semiconductor layer 13 and the TFT 21 including the semiconductor layer 13.

Next, a silicon nitride film, for example, is formed by plasma CVD on the entire substrate on which the TFT 21 is formed, to obtain the interlayer insulating film 15 with a thickness of about 4000 Å. The interlayer insulating film 15 is etched thereafter to form the contact hole 30.

Next, a transparent conductive film made of an ITO film, etc., is formed by sputtering on the entire substrate on the interlayer insulating film 15, and thereafter, patterning is performed by photolithography to form, on the insulating substrate 10, the transparent electrode 31 with a thickness of about 1000 Å. The above-described cutout 39 is formed at a predetermined position of the transparent electrode 31 at this time.

Next, a molybdenum film (having a thickness of about 750 Å) and an aluminum film (having a thickness of about 1000 Å) are sequentially formed by sputtering on the entire substrate on which the transparent electrode 31 is formed, and thereafter, patterning is performed by photolithography to form the reflection electrode 32 on a surface of the transparent electrode 31 in the reflection region R. As a result, the pixel electrode 19 including the transparent electrode 31 and the reflection electrode 32 is formed.

Next, a polyimide resin is applied by a printing method to the entire substrate on which the pixel electrode 19 is formed, and thereafter, a rubbing treatment is performed to form the alignment film 16 with a thickness of about 1000 Å.

The TFT substrate 5 can be formed in this manner.

<CF Substrate Formation Step>

First, an insulating substrate 46 such as a glass substrate is prepared. A positive photosensitive resin in which, for example, a black pigment such as carbon fine particles is dispersed is applied to the entire insulating substrate 46 by spin coating. The applied photosensitive resin is exposed through a photomask, developed and heated, thereby forming the black matrix 37.

Next, for example, a red-, green-, or blue-colored acrylic photosensitive resin is applied to the substrate on which the black matrix 37 is formed. The applied photosensitive resin is exposed through a photomask, and thereafter developed to pattern the photosensitive resin, thereby forming the color layer 38 of a selected color (e.g., a red color layer R) with a thickness of about 2.0 μm. Similar steps are repeated for the other two colors to form the color layers 38 of the two colors (e.g., a green color layer G and a blue color layer B) with a thickness of about 2.0 μm. As a result, the color filter layer 47 including the red color layer R, the green color layer G, and the blue color layer B is formed as shown in FIG. 7.

Next, an acrylic photosensitive resin is applied by spin coating to the substrate on which the color filter layer 47 is formed. The applied photosensitive resin is exposed through a photomask, and is developed thereafter, thereby forming the transparent dielectric layer 33 with a thickness of about 2 μm as shown in FIG. 8.

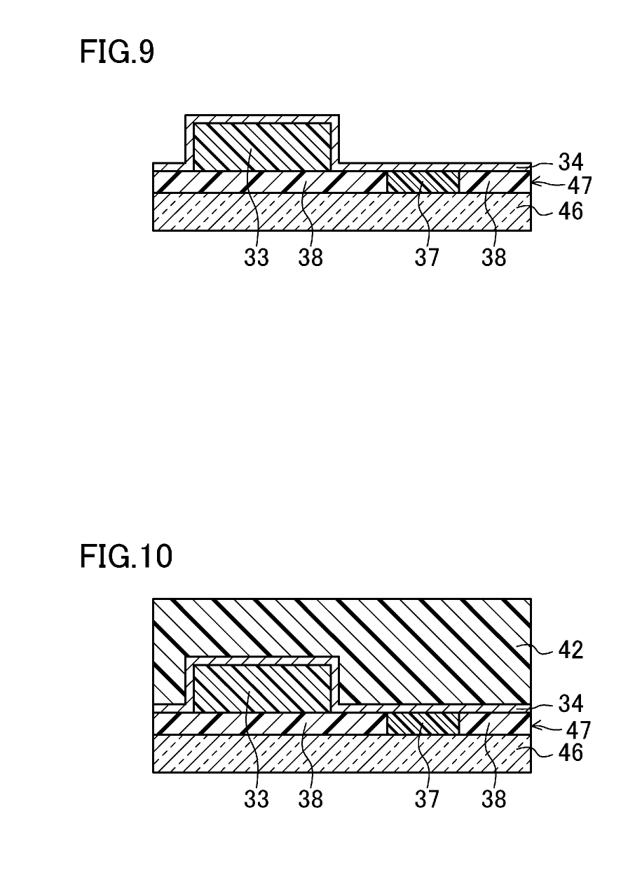

An ITO film, for example, is then formed by sputtering on the entire substrate on which the transparent dielectric layer 33 is formed, and thereafter, patterning is performed by photolithography to form the common electrode 34 with a thickness of about 1500 Å as shown in FIG. 9.

Next, the protrusion 25 and the photo spacers 35 are simultaneously formed by photolithography.

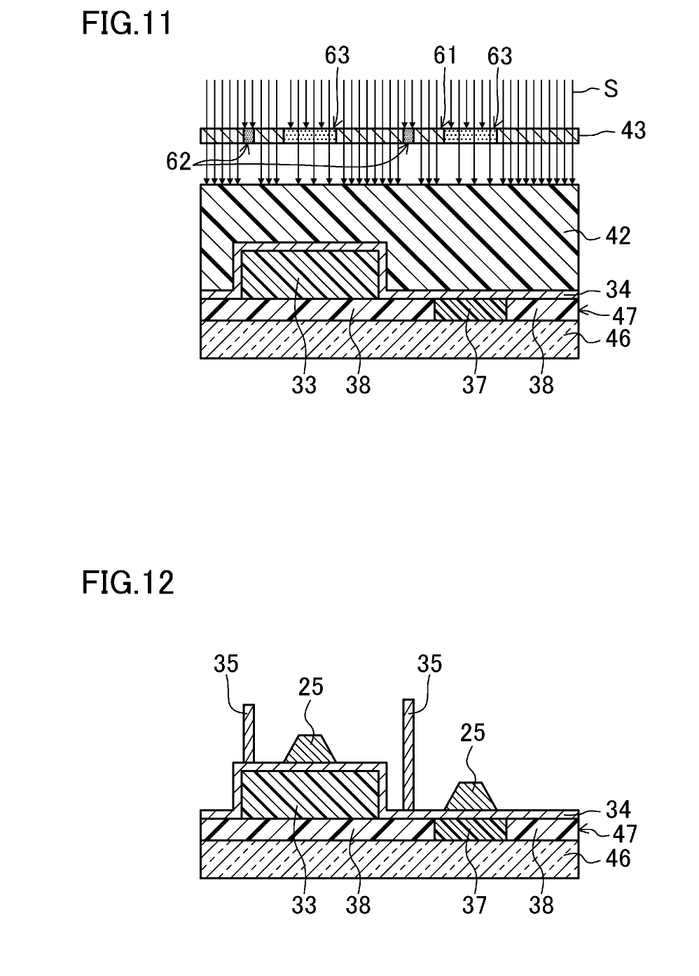

More specifically, as shown in FIG. 10, a positive photosensitive resin 42, such as an acrylic photosensitive resin, in which an exposed portion is dissolved and removed by development, is applied to the common electrode 34 by spin coating in a thickness of about 3.5 μm. After that, as shown in FIG. 11, the photosensitive resin 42 is exposed using a photomask 43, and is developed, thereby simultaneously forming the protrusion 25 with a thickness of 2.5 μm and the photo spacers 35 with a thickness of 3.5 μm as shown in FIG. 12.

In the present embodiment, as shown in FIG. 11, an exposure treatment (a half-tone exposure treatment or a gray-tone exposure treatment) is performed using a half-tone mask or a gray-tone mask as the photomask 43, thereby controlling an amount of exposure of the photosensitive resin 42.

That is, a half-tone mask or a gray-tone mask which has a different light transmittance depending on areas, is used as the photomask 43, and the photosensitive resin 42 is exposed through the photomask 43.

Such an exposure treatment allows the photosensitive resin 42 to be exposed by a different amount of exposure. Thus, the protrusions 25 and the photo spacers 35 can be formed at the same time using the same material as shown in FIG. 12 by developing the photosensitive resin 42 subjected to the above exposure treatment.

In the present embodiment, a photomask including a light transmitting portion 61 which transmits light, a light shielding portion 62 which does not transmit light at all, and a semi-light transmitting portion 63 which transmits light with an intermediate intensity is used as the photomask 43, as shown in FIG. 13.

For example, a light shielding layer 64 (such as Cr) is formed on the entire surface of the light shielding portion 62, and a plurality of light shielding layers 64 provided in stripes are formed in the semi-light transmitting portion 63. In the semi-light transmitting portion 63, each of the light shielding layers 64 has a width, for example, of 1.0 μm or more and 2.0 μm or less, and the interval between adjacent light shielding layers 64 is, for example, 1.0 μm or more and 2.0 μm or less.

The semi-light transmitting portion 63 has a fine stripe pattern due to the light shielding layers 64 as described above. Thus, when the photosensitive resin 42 is exposed through the semi-light transmitting portion 63, the photosensitive resin 42 is not exposed in stripes, but is exposed in an even manner by a smaller exposure amount than when exposed through the light transmitting portion 61 because the exposure amount is reduced by the light shielding layers 64.

FIG. 13 schematically shows the light transmitting portion 61, the light shielding portion 62, and the semi-light transmitting portion 63 so that the structure of the photomask 43 can be easily understood. The photomask 43 is configured such that the semi-light transmitting portion 63 is located above the region where the protrusion 25 is formed, and such that light shielding portion 62 is located above the region where the photo spacer 35 is formed, when the photomask 43 is positioned at a predetermined location facing the photosensitive resin 42.

To perform an exposure treatment on the photosensitive resin 42, the photomask 43 is positioned at a predetermined location facing the photosensitive resin 42 as shown in FIG. 11, and thereafter ultraviolet rays S are applied from the side opposite the insulating substrate 46 with respect to the photomask 43. The photosensitive resin 42 is exposed through the photomask 43 in this manner.

Next, the photosensitive resin 42 is developed. Specifically, the photosensitive resin 42 is immersed in a developing solution to dissolve and remove part of the photosensitive resin 42 to which the ultraviolet rays S are applied, and thereafter the entire substrate is cleaned.

Part of the photosensitive resin 42 which is prevented from being exposed due to the light shielding portion 62 remains, and serves as the photo spacer 35. Part of the photosensitive resin 42 which is exposed through the semi-light transmitting portion 63 remains, and serves as the protrusion 25.

Next, a polyimide resin is applied by a printing method to the entire substrate on which the protrusion 25 and the photo spacer 35 are formed, and thereafter, a rubbing treatment is performed to form the alignment film 9 with a thickness of about 1000 Å.

The CF substrate 6 can be formed in this manner.

<Bonding Step>

First, by using a dispenser, for example, the sealing material 7 made of an ultraviolet curable, thermosetting resin or the like, is applied in a frame shape to the CF substrate 6 formed by the above-described CF substrate formation step.

Next, a liquid crystal material is dropped onto a region surrounded by the sealing material 7 on the CF substrate 6.

The CF substrate 6 on which the liquid crystal material is dropped, and the TFT substrate 5 formed in the above-described TFT substrate formation step are bonded together under reduced pressure. Then, the bonded body is released in the atmospheric pressure to apply pressure to the front surface and the back surface of the bonded body.

Next, the sealing material 7 sandwiched in the bonded body is irradiated with UV light, and thereafter the bonded body is heated to cure the sealing material 7.

As described above, the obtained TFT substrate 5 and the CF substrate 6 are positioned to face each other, with the photo spacers 35 interposed therebetween, and are bonded together with the sealing material 7. The liquid crystal layer 8 is sealed in the gap between the substrates, thereby obtaining the liquid crystal display panel 2.

Next, the polarizing plates 3, 4 are provided on both sides of the liquid crystal display panel 2 in the thickness direction of the liquid crystal display panel 2, and a drive circuit and the backlight unit 40 are attached.

The liquid crystal display device 1 shown in FIG. 1 can be formed in this manner.

According to the present embodiment described above, the following advantages can be obtained.

(1) In the present embodiment, the protrusions 25 and the photo spacers 35 are formed at the same time by using the photomask 43 which controls the amount of exposure of the photosensitive resin 42 in an exposure treatment, and developing the photosensitive resin 42 subjected to the exposure treatment. Thus, the protrusions 25 and the photo spacers 35 can be formed at the same time using the same material (i.e., the photosensitive resin 42). Accordingly, it is not necessary to provide another step for forming the protrusion 25 which regulates the alignment of the liquid crystal molecules 8a comprising the liquid crystal layer 8. As a result, the protrusion 25 can be obtained without increasing the number of fabrication steps, which can prevent an increase in costs.

(2) In the present embodiment, a gray-tone mask or a half-tone mask is used as the photomask 43. Thus, the exposure treatment with different amounts of exposure can be easily performed on the photosensitive resin 42. As a result, the amount of exposure of the photosensitive resin 42 can be easily controlled.

(3) In the present embodiment, the protrusion 25 is provided at a center portion of the transmissive region T. Accordingly, the liquid crystal molecules 8a can be radially arranged in a well-balanced manner across the transmissive region T, with the center portion of the transmissive region T serving as a center of the alignment.

(4) In the present embodiment, the protrusion 25 is provided at a center portion of the reflection region R. Accordingly, the liquid crystal molecules 8a can be radially arranged in a well-balanced manner across the reflection region R, with the center portion of the reflection region R serving as a center of the alignment.

The above embodiment can be modified as follows.

In the above embodiment, the protrusions 25 are formed in both of the transmissive region T and the reflection region R, but the protrusion 25 may be formed in at least one of the transmissive region T or the reflection region R. Thus, it is possible to regulate the alignment of the liquid crystal molecules 8a comprising the liquid crystal layer 8 in at least one of the transmissive region T or the reflection region R.

The protrusion 25 and the photo spacer 35 may have the same thickness. That is, as shown in FIG. 14, when the thickness of the photo spacer 35 provided in the reflection region R is T₁, and the thickness of the protrusion 25 provided in the reflection region R is T₂, an equation of T₁=T₂ may be satisfied.

In this case, the amount of exposure of the photosensitive resin 42 is controlled in the exposure treatment such that the protrusion 25 and the photo spacer 35 have the same thicknesses T₂ and T₁, respectively, using the photomask in the step described in FIG. 11, and thereafter the photosensitive resin 42 subjected to the exposure treatment is developed. As a result, the protrusion 25 and the photo spacers 35 are formed at the same time with the same thickness.

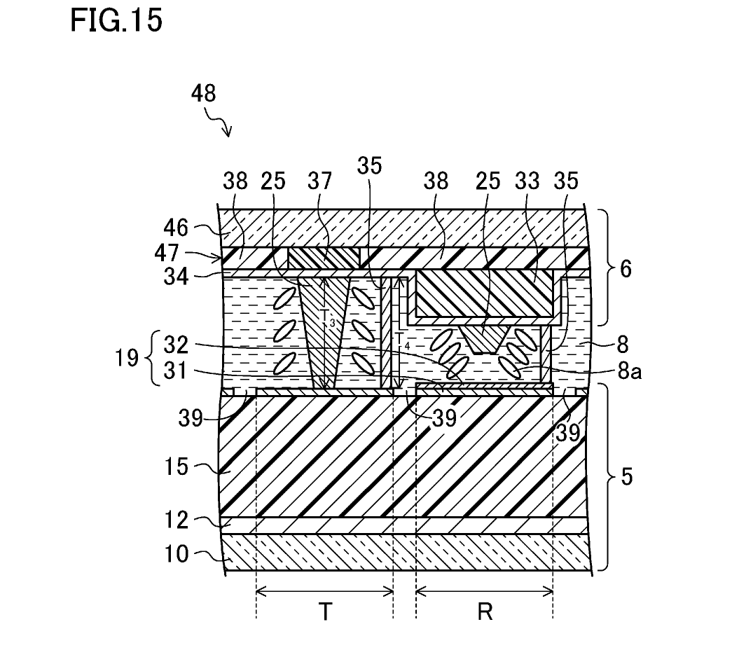

Similarly, as shown in FIG. 15, the protrusion 25 and the photo spacer 35 may be formed at the same time to satisfy the equation T₃=T₄, wherein the thickness of the protrusion 25 provided in the transmissive region T is T₃, and the thickness of the photo spacer 35 provided in the transmissive region T is T₄.

The protrusion 25 provided in the reflection region R and the photo spacer 35 provided in the reflection region R may have the same thickness, and the protrusion 25 provided in the transmissive region T and the photo spacer 35 provided in the transmissive region T may have the same thickness.

That is, it is only necessary that at least one of the plurality of protrusions 25 has the same thickness as the thickness of one of the photo spacers 35.

According to this structure, it is possible to increase the number of structures for regulating the thickness of the liquid crystal layer 8 without decreasing a transmittance or a reflectance. Thus, it is possible to effectively reduce distortion of an image, etc., which occurs when the display surface is pushed.

In the above embodiment, the protrusions 25 are formed on the common electrode 34 comprising the CF substrate 6, but may be formed on the TFT substrate 5. More specifically, the protrusions 25 may be formed on the pixel electrode 19 comprising the TFT substrate 5.

### INDUSTRIAL APPLICABILITY

As described above, the present disclosure is useful as a method for fabricating a liquid crystal display device in which a pair of substrates are layered, with a predetermined space interposed therebetween, and liquid crystal is sealed in the gap between the pair of substrates.

### DESCRIPTION OF REFERENCE CHARACTERS

1 liquid crystal display device
2 liquid crystal display panel
5 TFT substrate (first substrate)
6 CF substrate (second substrate)
8 liquid crystal layer
8a liquid crystal molecule
10 insulating substrate
10 protrusion
35 photo spacer
42 photosensitive resin
43 photomask
46 insulating substrate
48 pixel
D display region
T transmissive region
R reflection region

1. A method for fabricating a liquid crystal display device which comprises: a first substrate; a second substrate located to face the first substrate; a liquid crystal layer provided between the first substrate and the second substrate; a plurality of photo spacers provided between the first substrate and the second substrate to regulate a thickness of the liquid crystal layer; and a protrusion provided between the first substrate and the second substrate to regulate alignment of liquid crystal molecules included in the liquid crystal layer; and in which a display region that displays an image is comprised of a plurality of pixels, the method at least including:
preparing an insulating substrate as the first substrate or the second substrate,
providing a photosensitive resin onto the insulating substrate,
performing an exposure treatment by controlling an amount of exposure of the photosensitive resin using a photomask, and
developing the photosensitive resin subjected to the exposure treatment, thereby forming the protrusion and the photo spacers at the same time.

2. The method for fabricating the liquid crystal display device of claim 1, wherein
the photomask is a gray-tone mask or a half-tone mask.

3. The method for fabricating the liquid crystal display device of claim 1, wherein
each of the pixels includes a transmissive region which transmits light to display an image and a reflection region which reflects light to display an image, and
the protrusion is provided in at least one of the transmissive region or the reflection region.

4. The method for fabricating the liquid crystal display device of claim 3, wherein
the protrusion is provided at a center portion of the transmissive region.

5. The method for fabricating the liquid crystal display device of claim 3, wherein
the protrusion is provided at a center portion of the reflection region.

6. The method for fabricating the liquid crystal display device of claim 1, wherein
a thickness of the protrusion and a thickness of at least one of the photo spacers are the same.

7. The method for fabricating the liquid crystal display device of claim 1, wherein
the photosensitive resin is an acrylic photosensitive resin.
